(19) United States
(12) Patent Application Publication
(10) Pub. No.: US 2025/0098142 A1
(43) Pub. Date: Mar. 20, 2025

(54) DOUBLE CHANNEL SINGLE INNER GATE THREE-DIMENSIONAL (3D) DYNAMIC RANDOM-ACCESS MEMORY (DRAM) DEVICES

(71) Applicant: Applied Materials, Inc., Santa Clara, CA (US)

(72) Inventors: Tong LIU, San Jose, CA (US); Sony VARGHESE, Manchester, MA (US)

(21) Appl. No.: 18/812,803

(22) Filed: Aug. 22, 2024

Related U.S. Application Data
(60) Provisional application No. 63/539,456, filed on Sep. 20, 2023.

(51) Int. Cl. H10B 12/00

(52) U.S. Cl. CPC H10B 12/30; H10B 12/05

(57) ABSTRACT

A memory cell array includes a plurality of memory levels stacked in a first direction, each of the plurality of memory levels including a cell transistor having a source region electrically connected to a bit line extending in the first direction, a drain region, a word line layer, a lower channel layer electrically connected to the source region and the drain region and disposed below the word line layer in the first direction, and an upper channel layer electrically connected to the source region and the drain region and disposed above the word line layer in the first direction, and a cell capacitor electrically connected to the drain region, and a plurality of inter-level isolation layers, each separating adjacent memory levels of the plurality of memory levels.

### CROSS-REFERENCE TO RELATED APPLICATIONS

This application claims priority to U.S. Provisional Application Ser. No. 63/539,456 filed Sep. 20, 2023, which is herein incorporated by reference in its entirety.

### BACKGROUND

### Field

Embodiments described herein generally relate to semiconductor device fabrication, and more particularly, to double-channeled single-gated three-dimensional dynamic random-access memory devices and methods of forming thereof.

### Description of the Related Art

Three-dimensional (3D) dynamic random-access memory (DRAM) devices pose challenges in manufacturability due to their three-dimensional (3D) designs and small sizes. As the number of vertical stacks of memory cells in 3D DRAM devices increase (e.g., as chip densities increase), the height of each of the vertical stacks needs to be reduced. Typically, a 3D DRAM device includes individual memory cells, each of which includes a field-effect transistor (FET) having a double gated structure, in which two gates (and word lines connected to the two gates) are disposed on the sides of a silicon channel along the direction of the vertical stacks. However, due to a reduced thickness of the gates and the word lines, the word lines may have a high resistivity. Furthermore, DRAM devices are susceptible to a floating body effect caused by a high voltage potential from a drain to a gate, which deteriorates dynamic retention of an OFF state and increases a leak current.

Therefore, there is a need for 3D DRAM device structures in which word lines have low resistivity and a floating body effect can be reduced, and methods for fabrication of such 3D DRAM device structures.

### SUMMARY

Embodiments of the present disclosure provide a memory cell array. The memory cell array includes a plurality of memory levels stacked in a first direction, each of the plurality of memory levels including a cell transistor having a source region electrically connected to a bit line extending in the first direction, a drain region, a word line layer, a lower channel layer electrically connected to the source region and the drain region and disposed below the word line layer in the first direction, and an upper channel layer electrically connected to the source region and the drain region and disposed above the word line layer in the first direction, and a cell capacitor electrically connected to the drain region, and a plurality of inter-level isolation layers, each separating adjacent memory levels of the plurality of memory levels.

Embodiments of the present disclosure provide a method of forming cell transistors in a semiconductor memory device. The method includes performing a word line (WL) slit fill process, to fill WL slits formed in a stacking mold with a nitride layer, wherein the stacking mold comprises a plurality of unit stacks, each unit stack including a lower sacrificial layer, a lower channel layer over the lower sacrificial layer, an upper sacrificial layer on the lower channel layer, and an upper channel layer on the upper sacrificial layer stacked in a first direction, each unit stack has DTI gaps partially filled with an insulator layer and extending in a second direction that is orthogonal to the first direction, and the WL slits are each disposed between the lower channel layer and the upper channel layer between adjacent unit stacks of the stacking mold, selectively removing the insulator layer within the DTI gaps, and selectively removing the lower sacrificial layer and forming inter-level isolation gaps each between the lower channel layer and the upper channel layer between adjacent unit stacks of the stacking mold.

Embodiments of the present disclosure provide a method of forming cell transistors in a semiconductor memory device. The method includes forming a transistor slit through a stacking mold in a first direction, the transistor slit extending in a second direction that is orthogonal to the first direction, the stacking mold comprising a plurality of unit stacks, each unit stack including a lower sacrificial layer, a lower channel layer over the lower sacrificial layer, an upper sacrificial layer on the lower channel layer, and an upper channel layer on the upper sacrificial layer stacked in the first direction, performing a recess forming process, to form recesses in the upper sacrificial layers from sidewalls of the transistor slit, forming a first insulator layer on exposed surfaces of the lower channel layers and the upper channel layers within the transistor slit and the recesses, filling the transistor slit and the recesses with a first nitride layer, performing a deep trench isolation (DTI) lateral cut process, to form DTI gaps through the stacking mold in the first direction, the DTI gaps extending in a third direction that is orthogonal to the first and second directions, filling the DTI gaps with a second insulator layer, selectively removing the first nitride layer from the transistor slit and the recesses, forming word line (WL) slits each between the lower channel layer and the upper channel layer between adjacent unit stacks of the stacking mold, performing a WL slit fill process, to fill the WL slits and the recesses with a second nitride layer, selectively removing the second insulator layer, selectively removing the lower sacrificial layer and forming inter-level isolation gaps each between the lower channel layer and the upper channel layer between adjacent unit stacks of the stacking mold, filling the inter-level isolation gaps with inter-level isolation layers, performing a gate oxide formation process, to form a gate oxide layer on exposed inner surfaces of the WL slit and the recesses, and performing a WL slit fill process, to fill the WL slits with a word line layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a multi-chamber processing system, according to one or more embodiments of the present disclosure.

FIG. 2A is a schematic view of a portion of a three-dimensional (3D) memory cell array of dynamic random access memory (DRAM) cells according to one embodiment.

FIG. 2B is a schematic diagram of a DRAM cell.

FIG. 3A is a cross-sectional view of a portion of a conventional single channel/dual gate semiconductor structure.

FIG. 3B is a cross-sectional view of a portion of a dual-channel/single inner gate semiconductor structure according to one embodiment.

FIGS. 4A and 4B depict a process flow diagram of a method of forming cell transistors in a semiconductor structure according to one embodiment.

FIGS. 5A, 5B, 5C, 5D, 5E, 5F, 5G, 5H, 5I, 5J, 5P, 5Q, and 5R are isometric views of a portion of a semiconductor structure corresponding to various states of the method of FIGS. 4A and 4B.

FIGS. 5H′, 5I′, 5J′, 5K′, 5L′, 5M′, 5N′, 5O′, 5P′, and 5Q′ are cross-sectional views of a portion of the semiconductor structure corresponding to various states of the method of FIGS. 4A and 4B, along the YZ plane including the line A-A′ shown in FIGS. 5H and 5J.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide double channeled single gated three-dimensional (3D) dynamic random-access memory (DRAM) devices and methods for forming cell transistors in such 3D DRAM devices. Due to double channels and a single inner gate sandwiched by the double channels between a source and a drain, a floating body effect caused by a high electric field induced between a drain to a gate can be reduced, and higher electrical current can be driven via the double channels. Furthermore, the double channels can be formed thin (e.g., less than about 10 nm), which further reduces a floating body effect and thus a leakage current can be reduced and dynamic retention of an OFF state can be increased. A word line layer that includes a single inner gate and a word line between the double gates can be formed with a uniform thickness, and thus with an improved resistivity, by the methods described herein.

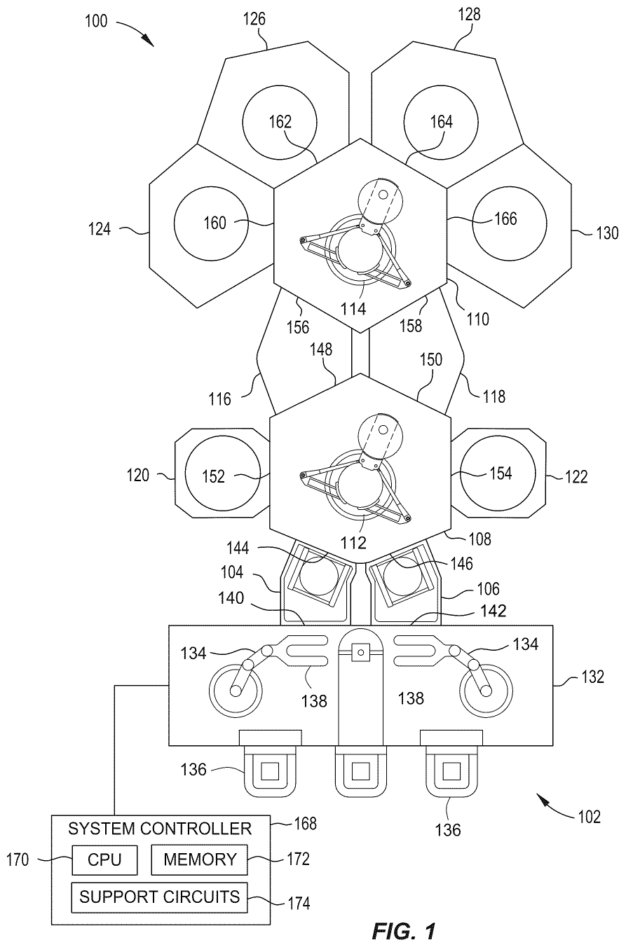

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing etch processes, the processing chamber 122 can be capable of performing cleaning processes, the processing chamber 124 can be capable of performing selective removal processes, the processing chamber 126 can be capable of performing chemical vapor deposition (CVD) deposition processes, and the processing chambers 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126 may be a W×Z™ chamber available from Applied Materials of Santa Clara, Calif. The processing chamber 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

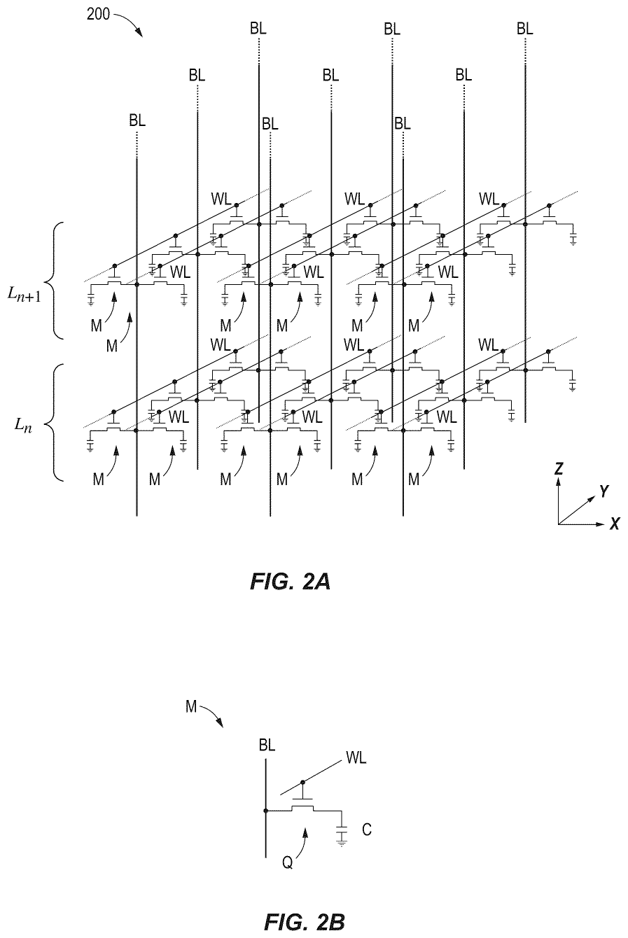

FIG. 2A is a schematic diagram of a portion of a three-dimensional (3D) memory cell array 200 of dynamic random access memory (DRAM) cells (also referred to as “memory cells”) M, according to one or more embodiments of the present disclosure.

As shown in FIG. 2B, a single memory cell M includes an access transistor Q and a storage capacitor C. A memory cell M stores a datum bit by storing a packet of charge (i.e., a binary one) or no charge (i.e., a binary zero) on the storage capacitor C. A datum bit is input and output by a bit line BL that is connected to the source/drain of the access transistor Q, and input is controlled by a word line WL that is connected to the gate of the access transistor Q.

The memory cell array 200 includes memory levels Lₙ (n=1, 2, . . . ) (a first memory level L₁ and a second memory level L₂ are shown) stacked in the Z direction. Each memory level Lₙ includes two-dimensional (2-D) array of memory cells M. Although only two memory levels are shown in FIG. 2A, the memory cell array 200 may include more memory levels Lₙ (n=3, 4, . . . ) stacked above the second memory level L₂ in the Z direction.

In the memory cell array 200, bit lines BL extend vertically in the Z direction, and word lines WL extend horizontally in the Y-direction. Each of the bit lines BL is linked to the sources/drains of access transistors Q that are vertically aligned in the Z direction. Each of the word lines WL is linked to the gates of the access transistors that are horizontally aligned in the Y direction.

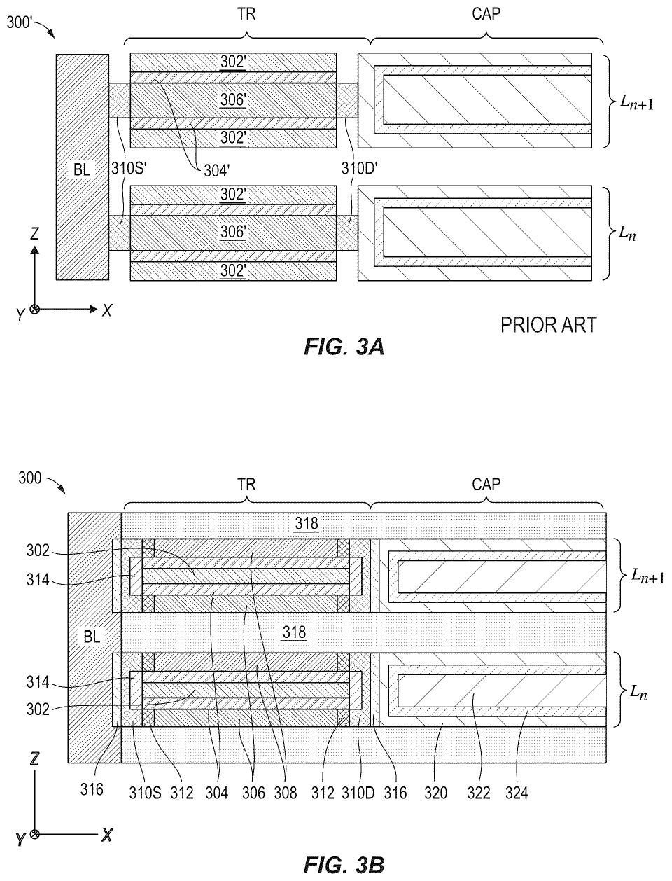

FIG. 3A is a cross-sectional view of a portion of a conventional single channel/dual gate semiconductor structure 300′ that may form a 3D memory cell array, such as a portion of the memory cell array 200. As shown, there are memory levels Lₙ and Lₙ₊₁ (n=1, 2, 3, . . . ) are stacked in the Z direction on a substrate (not shown).

The semiconductor structure 300′ includes a FET module TR and a capacitor module CAP adjacent to the FET module TR in the X direction. The FET module TR and the capacitor module C are divided into multiple sections in the Y direction. The FET module TR and the capacitor module C in each memory level Lₙ (n=1, 2, . . . ) in each section form an access transistor (also referred to as a “cell transistor”) Q and a storage capacitor (also referred to as “cell capacitor”) C, respectively, which together form a memory cell M.

The FET module TR in the memory level Lₙ (n=1, 2, 3, . . . ) (referred to as a cell transistor Qₙ) in the conventional single channel/dual gate semiconductor structure 300′ includes two word line layers 302′, surrounded by a gate oxide layer 304′, and a single channel layer 306′ sandwiched between the word line layers 302′ in the Z direction. The word line layers 302′ may each be of a thickness of about 5 nm. The single channel layer 306′ may be of a thickness of about 20 nm. The single channel layer 306′ is electrically connected to a source region 310S′ and to a drain region 310D′. The source region 310S′ is electrically connected to a bit line BL. The capacitor module CAP is connected to the drain region 310D′.

FIG. 3B is a cross-sectional view of a portion of a dual-channel/single inner gate semiconductor structure 300 that may form a 3D memory cell array, such as a portion of the memory cell array 200, according to one or more embodiments of the present disclosure. As shown, there are memory levels Lₙ and Lₙ₊1 (n=1, 2, 3, . . . ) are stacked in the Z direction on a substrate (not shown).

The semiconductor structure 300 includes a FET module TR and a capacitor module CAP adjacent to the FET module TR in the X direction. The FET module TR and the capacitor module C are divided into multiple sections in the Y direction. The FET module TR and the capacitor module C in each memory level Lₙ (n=1, 2, . . . ) in each section form an access transistor (also referred to as a “cell transistor”) Q and a storage capacitor (also referred to as “cell capacitor”) C, respectively, which together form a memory cell M.

The FET module TR in the memory level Lₙ (n=1, 2, 3, . . . ) (referred to as a cell transistor Qₙ) includes a word line layer 302 encapsulated by a gate oxide layer 304. The word line layer 302 extending in the Y direction and includes a single inner gate (not shown in FIG. 3A) of the cell transistor Qₙ. The cell transistor Qₙ further includes a lower channel layer 306 below the word line layer 302 and an upper channel layer 308 above the word line layer 302 in the Z direction. On both sides of the word line layer 302 in the X direction, source/drain (S/D) regions 310S, 310D are electrically connected to the lower channel layers 306 and the upper channel layers 308 via extension regions 312, and interfaced with the word line layer 302 with spacer layers 314. The S/D regions 310S, 310D act as source/drain of the cell transistor Qₙ. A bit line BL is electrically connected the source regions 310S in all memory levels via an interface 316.

As compared to the conventional single channel/dual gate semiconductor structure 300′ shown in FIG. 3A, the single word line layer 302 can be thicker in the Z direction (e.g., about 10 nm). Furthermore, the single word line layer 302 can be formed of a uniform thickness, by the methods described herein. Thus, resistivity of the word line layer 302 can be improved. The dual-channel/single inner gate semiconductor structure 300 may provide a lower leakage current and better dynamic retention due to a lower floating body effect.

The FET module TR in the memory level Lₙ (n=1, 2, 3, . . . ) (cell transistors Qₙ) is separated from the FET module TR in adjacent memory level Lₙ₊₁ (cell transistors Qₙ₊₁) by an inter-level isolation layer 318.

The word line layers 302 may be formed from tungsten (W), cobalt (Co), ruthenium (Ru), molybdenum (Mo), titanium nitride (TiN), iridium (Ir), tantalum (Ta), tantalum nitride (TaN), platinum (Pt), rhodium (Rh), or conductive oxides or nitrides thereof, or any combination thereof. The word line layers 302 may each have a thickness in the Z direction of between about 5 nm and about 20 nm, for example, about 10 nm.

The gate oxide layers 304 may be formed of silicon oxide (SiO₂), silicon oxynitride (SiON), a high-κ dielectric material, such as hafnium oxide (HfO₂), zirconium oxide (ZrO₂), aluminum oxide (Al₂O₃), hafnium silicon oxide (HfSiO), zirconium silicon oxide (ZrSiO), tantalum pentoxide (Ta₂O₅), tantalum silicon oxide (TaSiO), or any combination thereof. The gate oxide layers 304 may each have a thickness in the Z direction of between about 4 nm and about 8 nm, for example, about 5 nm.

The lower channel layers 306 and the upper channel layers 308 may be formed of silicon (Si), germanium (Ge), silicon germanium (SiGe), or indium gallium zinc oxide (IGZO). The lower channel layers 306 and the upper channel layers 308 may have a thickness in the Z direction of between about 5 nm and about 10 nm, for example, about 10 nm.

The S/D regions 310S, 310D and the extension regions 312 may be formed of silicon (Si) or indium gallium zinc oxide (IGZO). The S/D regions 310S, 310D may be epitaxially grown, and thus may not be collapsed when height of each of memory levels Lₙ (n=1, 2, . . . ) is reduced. The S/D regions 310S, 310D may be doped with n-type dopants, such as phosphorus (P), arsenic (As), or antimony (Sb), with the concentration of between about 10²⁰ cm⁻³ and about 10²¹ cm⁻³. The extension regions 312 may be lightly doped with n-type dopants, such as phosphorus (P), arsenic (As), or antimony (Sb), with the concentration of between about 10¹⁸ cm⁻³ and about 10¹⁹ cm⁻³.

The S/D regions 310S, 310D may each have a thickness in the Z direction, which corresponds to a total thickness of the word line layer 302, the gate oxide layers 304, the lower channel layer 306, and the upper channel layer 308 within the memory level Lₙ, of between about 25 nm and about 55 nm, for example, about 40 nm.

The spacer layers 314 may be formed of dielectric material, such as silicon nitride (Si₃N₄), silicon oxynitride (SiON), silicon carbonitride (SiCN), silicon oxycarbide (SiOC).

The interface 316 may be formed of metal silicide, such as titanium silicide (TiSi, TiSi₂), nickel silicide (NiSi, Ni₂Si), molybdenum silicide (MoSi, MoSi₂), cobalt silicide (CoSi₂), tantalum silicide (TaSi₂), or any combination thereof.

The inter-level isolation layer 318 may be formed of dielectric material, such as silicon dioxide (SiO₂), silicon oxynitride (SiON), silicon oxycarbide (SiOC), boron-doped silicon oxycarbonitride (SiOCBN), or any combination thereof.

The bit line BL may be formed of metal such as tungsten (W), molybdenum (Mo), titanium (Ti), cobalt (Co), nickel (Ni), tantalum (Ta), titanium nitride (TiN), tantalum nitride (TaN), doped polysilicon (poly), or any combination thereof. The bit line BL may have width in the Y direction of between about 70 nm and about 120 nm, for example, about 90 nm, and thickness in the X direction of between about 70 nm and about 120 nm, for example, about 80 nm.

The capacitor module CAP in the memory level Lₙ (n=1, 2, 3, . . . ) includes a bottom electrode layer 320 that is electrically connected to the drain region 310D via the interface 316 within the memory level Lₙ, a top electrode layer 322 that is grounded (not shown), and a high-k dielectric layer 324 between the bottom electrode layer 320 and the top electrode layer 322. The bottom electrode layer 320 and the top electrode layer 322 may serve as two plates of a capacitor C. The bottom electrode layer 320 and the top electrode layer 322 may be formed of titanium nitride (TiN), cobalt (Co), tungsten (W), aluminum (AI), ruthenium (Ru), iridium (Ir), molybdenum (Mo), platinum (Pt), tantalum (Ta), titanium (Ti), rhodium (Rh), or conductive metal nitrides, or any combination thereof. The high-k dielectric layer 324 may be formed of a high-k dielectric material such as, hafnium oxide (HfO₂), zirconium oxide (ZrO₂), aluminum oxide (Al₂O₃), vanadium oxide (VO₂), titanium oxide (TiO₂), tin oxide (SnO₂), zinc oxide (ZnO), hafnium silicon oxide (HfSiO), zirconium silicon oxide (ZrSiO), niobium oxide (Nb₂O₅), tantalum pentoxide (Ta₂O₅), or any combination thereof.

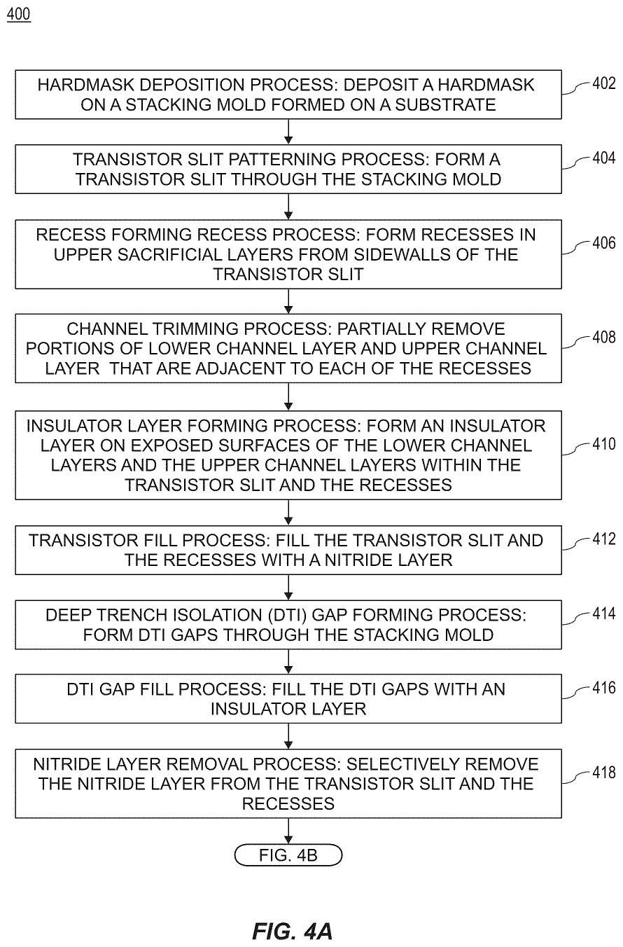

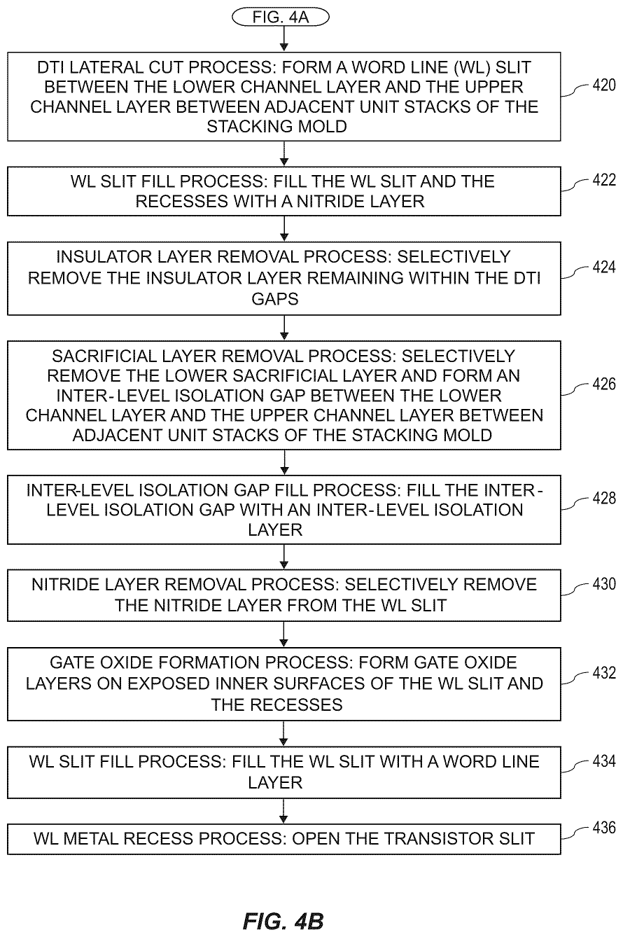

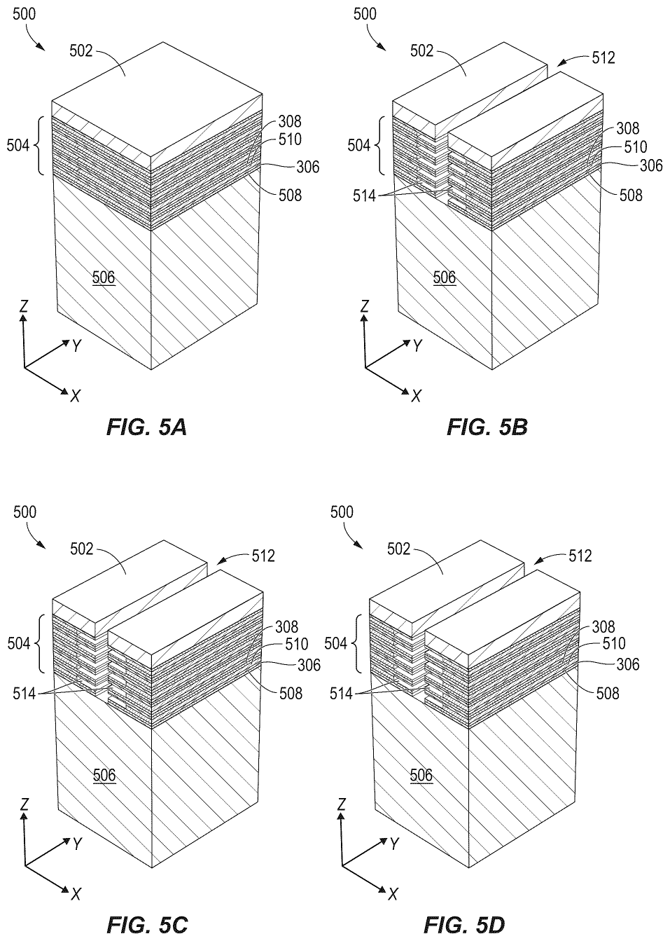

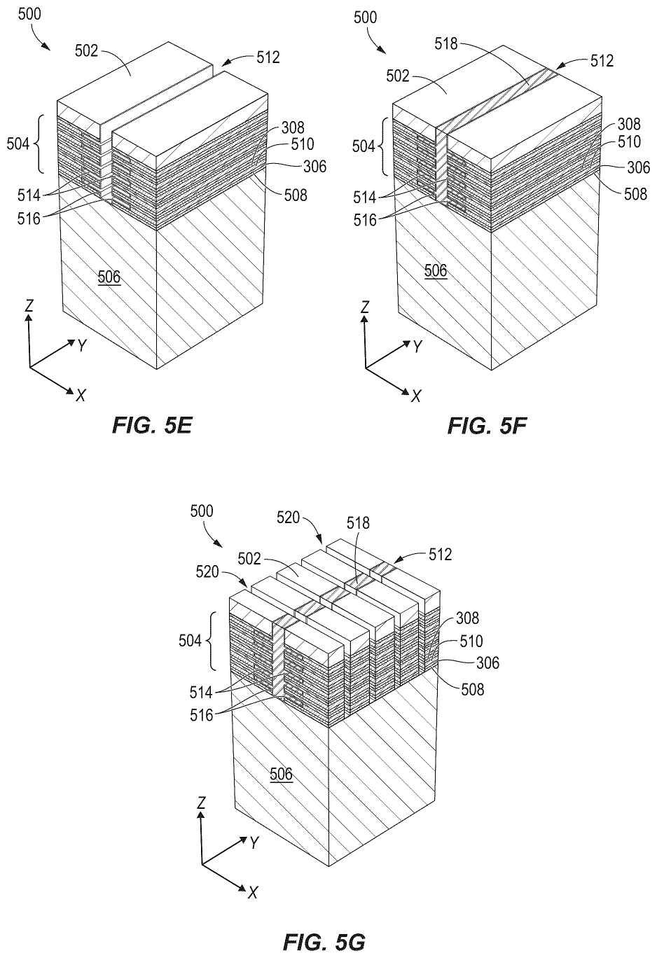

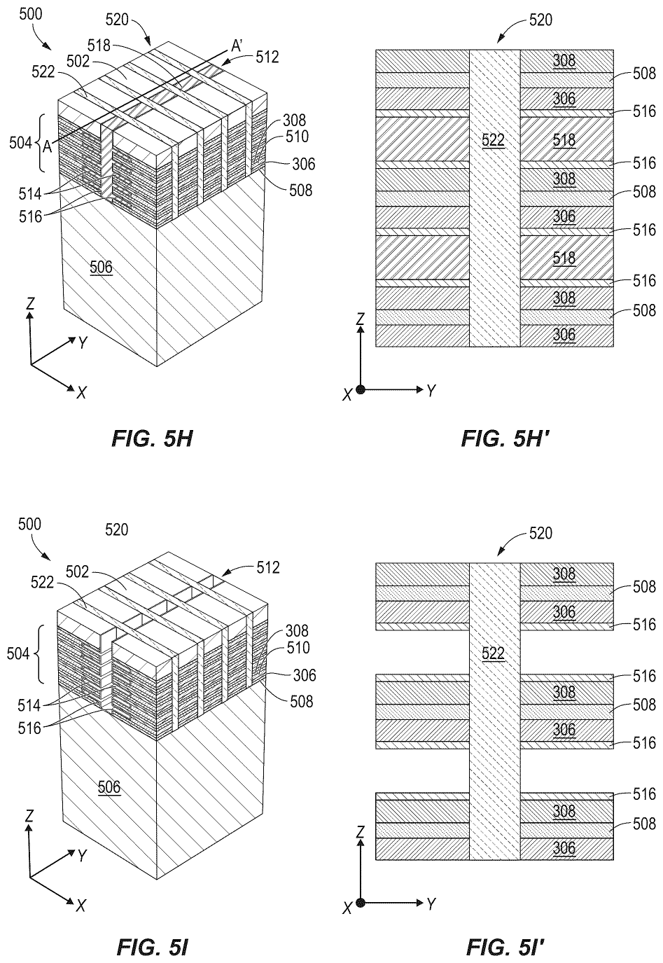

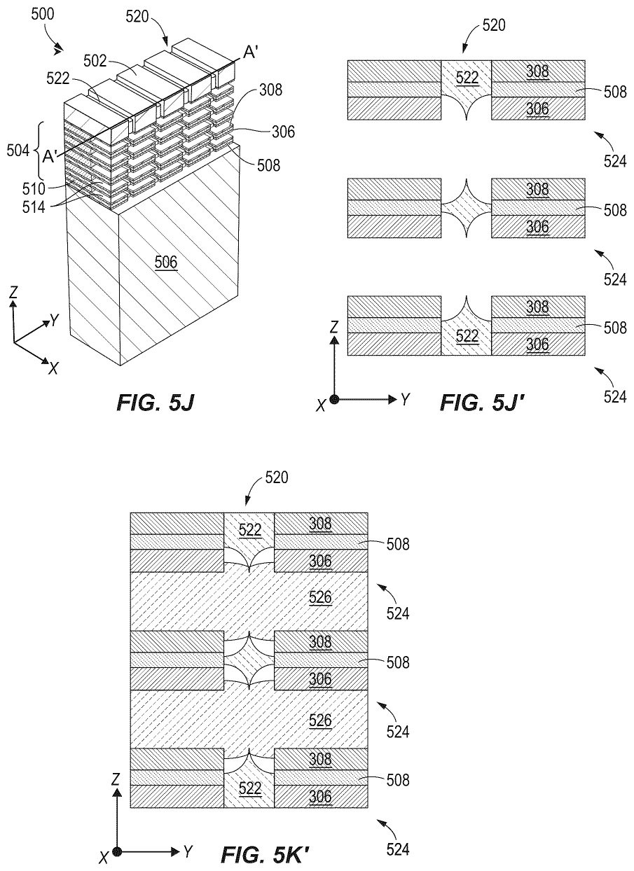

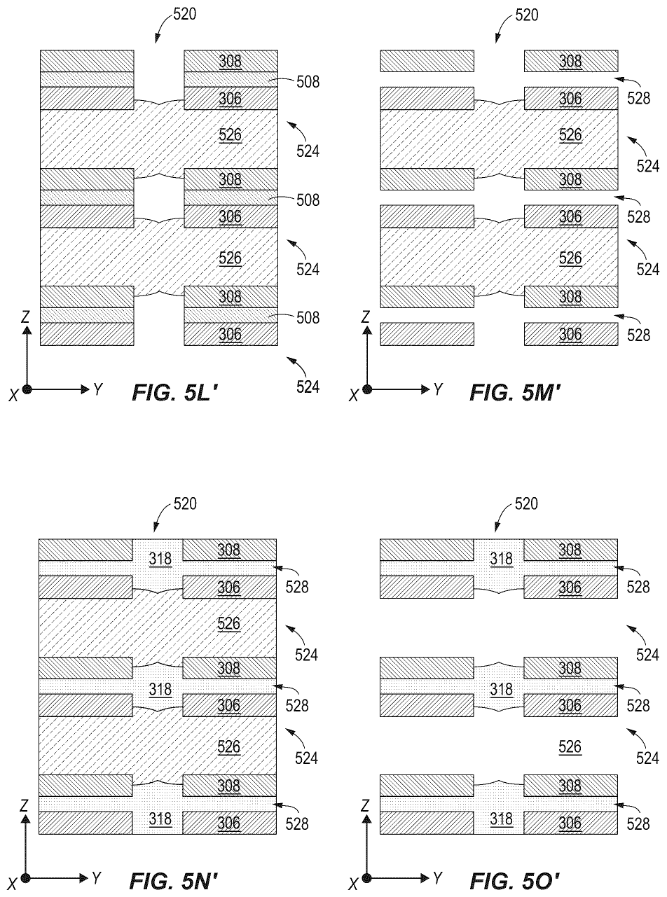

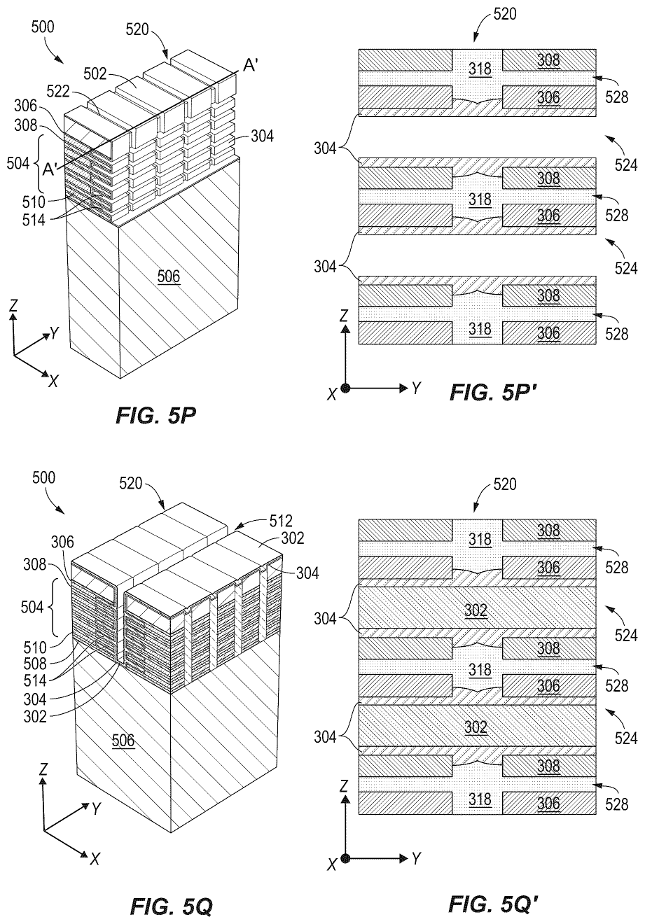

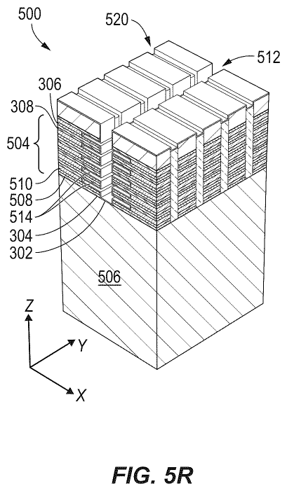

FIGS. 4A and 4B depict a process flow diagram of a method 400 of forming cell transistors in a semiconductor structure 500 that may form a FET module TR of the semiconductor structure 300 shown in FIG. 3B. FIGS. 5A, 5B, 5C, 5D, 5E, 5F, 5G, 5H, 5I, 5J, 5P, 5Q, and 5R are isometric views of a portion of the semiconductor structure 500 corresponding to various states of the method 400. FIGS. 5H′, 5I′, 5J′, 5K′, 5L′, 5M′, 5N′ 5O′, 5P′, and 5Q′ are cross-sectional views of a portion of the semiconductor structure 500 corresponding to various states of the method 400, along the YZ plane including the line A-A′ shown in FIGS. 5H and 5J. It should be understood that FIGS. 5A, 5B, 5C, 5D, 5E, 5F, 5G, 5H, 5H′ 5I, 5I′ 5J, 5J′, 5K′, 5L′, 5M′, 5N′, 5O′, 5P, 5P′, 5Q, 5Q′, and 5R illustrate only partial schematic views of the semiconductor structure 500, and the semiconductor structure 500 may contain any number of transistor sections and additional materials having aspects as illustrated in the figures. It should also be noted that although the method illustrated in FIGS. 4A and 4B is described sequentially, other process sequences that include one or more operations that have been omitted and/or added, and/or has been rearranged in another desirable order, fall within the scope of the embodiments of the disclosure provided herein.

The method 400 begins with block 402, in which a hardmask deposition process is performed to deposit a hardmask 502 on a stacking mold 504 formed on a substrate 506, as shown in FIG. 5A. The hardmask deposition process may include any conventional deposition process, such as a chemical vapor deposition (CVD) process, a physical vapor deposition (PVD) process, an atomic layer deposition (ALD) process, and a spin-on process performed in a processing chamber, such as the processing chamber 126, 128, or 130 shown in FIG. 1. The hardmask 502 may be subsequently patterned by a conventional photolithographic process using a patterned photoresist layer (not shown) covering the hardmask 502.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire.

The hardmask 502 may be formed of tetra-ethyl-orthosilicate (TEOS) or silicon oxynitride (SiON) and have a thickness of between about 500 nm and about 1 μm.

The stacking mold 504 includes multiple unit stacks of a lower sacrificial layer 508, a lower channel layer 306 on the lower sacrificial layer 508, an upper sacrificial layer 510 on the lower channel layer 306, and an upper channel layer 308 on the upper sacrificial layer 510 stacked in the Z direction, formed by any appropriate deposition process, such as epitaxial deposition process. The lower channel layers 306 and the upper channel layers 308 may be formed of first material. The lower sacrificial layers 508 may be formed of second material. The upper sacrificial layer 510 may be formed of third material. The etch selectivity of the second material and the third material against the first material (i.e., a ratio of the etch rates of the second material and the third material to the etch rate of the first material) is between about 10:1 to 500:1. Examples of the first material include silicon (Si), germanium (Ge), silicon germanium (SiGe), or indium gallium zinc oxide (IGZO). Examples of the second material and the third material include silicon germanium (SiGe) having germanium (Ge) concentration of between about 1% and about 50%), silicon carbide (SiC), phosphorus doped silicon germanium (SiGe:P), boron doped silicon germanium (SiGe:B), carbon doped silicon germanium (SiGe:C). The second material and the third material may be different materials that also have an etch selectivity therebetween. The lower channel layers 306 and the upper channel layers 308 each have a thickness of between about 5 nm and about 10 nm. The lower sacrificial layers 508 each have a thickness of between about 8 nm and about 15 nm. The upper sacrificial layers 510 each have a thickness of between about 30 nm and about 60 nm, which may be about five times thicker than the lower sacrificial layers 508. The second material and the third material may be the same as the difference in thickness between the lower sacrificial layer 508 and the upper sacrificial layer 510 may provide etch selectivity between the lower sacrificial layer 508 and the upper sacrificial layer 510. In the example shown in FIG. 5A, the number of unit stacks of the lower sacrificial layer 508, the lower channel layer 306, the upper sacrificial layer 510, and the upper channel layer 308 is five. However, the number of unit stacks may be larger than 50, for example, about 100.

In block 404, a transistor slit patterning process is performed to form a transistor slit 512 extending in the Y direction through the stacking mold 504 in the Z direction, as shown in FIG. 5B. The transistor slit patterning process may include any appropriate lithography and etch processes, such as photolithography.

The transistor slit 512 extends in the Y direction and may have a width in the X direction of between about 70 nm and about 120 nm.

In block 406, a recess forming recess process is performed to form recesses 514 in the upper sacrificial layers 510 from sidewalls of the transistor slit 512, as shown in FIG. 5C. The recess forming process may include any appropriate wet etching process, performed in a processing chamber, such as the processing chamber 120 shown in FIG. 1. The recess forming process may include a wet etch process using hydrofluoric acid (HF)-hydrogen peroxide (H₂O₂)-based mixtures, for example, a mixture of hydrofluoric acid (HF), hydrogen peroxide (H₂O₂), and acetic acid (CH₃COOH), in a volume ratio of 1:2:3.

The recesses 514 each have a height corresponding to the thickness of the upper sacrificial layer 510, and a width in the X direction of between 50 nm and about 200 nm.

In block 408, a channel trimming process is performed to partially remove portions of the lower channel layer 306 and the upper channel layer 308 that are adjacent to each of the recesses 514 in the Z direction, as shown in FIG. 5D. The channel trimming process may include any appropriate wet etching process, performed in a processing chamber, such as the processing chamber 120 shown in FIG. 1. The channel trimming process may include a wet etch process using tetramethyl ammonium hydroxide (TMAH, (CH₃)₄NOH) with high etch selectivity against silicon oxide (SiO₂).

The lower channel layers 306 and the upper channel layers 308 may be etched to a thickness of between about 1 nm and about 5 nm, for example, about 3 nm.

In block 410, an insulator layer forming process is performed to form an insulator layer 516 on exposed surfaces of the lower channel layers 306 and the upper channel layers 308 within the transistor slit 512 and the recesses 514, as shown in FIG. 5E. The insulator layer forming process may include any appropriate deposition process, such as chemical vapor deposition (CVD), physical vapor deposition (PVD), or the like performed in a processing chamber, such as the processing chamber 126, 128, or 130 shown in FIG. 1.

The insulator layer 516 may be formed of dielectric material, such as silicon oxide (SiO₂) and have a thickness of between about 3 nm and about 7 nm.

In block 412, a transistor fill process is performed to fill the transistor slit 512 and the recesses 514 with a nitride layer 518, as shown in FIG. 5F. The transistor slit fill process may include any appropriate deposition process, such as chemical vapor deposition (CVD), physical vapor deposition (PVD), or the like performed in a processing chamber, such as the processing chamber 126, 128, or 130 shown in FIG. 1.

The nitride layer 518 may be formed of dielectric material, such as silicon nitride (Si₃N₄), that has etch selectivity from the insulator layer 516.

In block 414, a deep trench isolation (DTI) gap forming process is performed to form DTI gaps 520 extending in the X direction through the stacking mold 504 in the Z direction, as shown in FIG. 5G. The DTI gap forming process may include any appropriate lithography and etch processes, such as photolithography.

The DTI gaps 520 extend in the X direction and may each have a width in the Y direction of between about 20 nm and about 50 nm, for example about 35 nm. The DTI gaps 520 may have an aspect ratio (a ratio of the depth to the width) of between 50 and 230.

In block 416, a DTI gap fill process is performed to fill the DTI gaps 520 with an insulator layer 522, as shown in FIGS. 5H and 5H′. The DTI gap fill process may include any appropriate deposition process, such as chemical vapor deposition (CVD), physical vapor deposition (PVD), or the like performed in a processing chamber, such as the processing chamber 126, 128, or 130 shown in FIG. 1.

The insulator layer 522 is formed of dielectric material, such as silicon oxide (SiO₂), that has etch selectivity from the nitride layer 518.

In block 418, a nitride layer removal process is performed to selectively remove the nitride layer 518 from the transistor slit 512 and the recesses 514, as shown in FIGS. 5l and 5l′. The nitride layer removal process may include any appropriate wet etching process, performed in a processing chamber, such as the processing chamber 120 shown in FIG. 1. The nitride layer removal process may include a wet etch process using phosphoric acid (H₃PO₄).

In block 420, a DTI lateral cut process is performed to remove portions of the insulator layers 522 (e.g., silicon oxide (SiO₂)) within the DTI gaps 520 adjacent to the recesses 514 in the Y direction and the insulator layer 516 (e.g., silicon oxide (SiO₂)) within the recesses 514, and form a word line (WL) slit 524 between the lower channel layer 306 and the upper channel layer 308 between adjacent unit stacks of the stacking mold 504, as shown in FIGS. 5J and 5J′. A cut-out of the semiconductor structure 500 along the YZ plane including the line A-A′ is shown in FIG. 5J. The DTI lateral cut process may include any appropriate wet etching process, performed in a processing chamber, such as the processing chamber 120 shown in FIG. 1. The DTI lateral cut process may include a wet etch process using hydrofluoric acid (HF) solution. The remaining portions of the insulator layers 522 and consequently the WL slits 524 may not have a uniform thickness be in the Z direction, having a scallop shape, due to wet etching from the recesses 514. Thus, in the embodiments described herein, the thickness of the WL slits 524 will be made uniform in the following steps before forming word line layers 302 within the WL slits 524 in block 434.

In block 422, a WL slit fill process is performed to fill the WL slit 524 and the recesses 514 with a nitride layer 526, as shown in FIG. 5K′. The WL slit fill process may include any non-conformal gap fill process, such as chemical vapor deposition (CVD) process.

The nitride layer 526 may be formed of dielectric material, such as silicon nitride (Si₃N₄), that has etch selectivity from the insulator layer 522. The nitride layer 526 may further include a thin silicon oxide (SiO₂) layer with a thickness of between about 1 nm and about 3 nm. Thickness of the deposited nitride layer 526 may be more uniform than the insulator layer 522 remaining within the DTI gaps 520.

In block 424, an insulator layer removal process is performed to selectively remove the insulator layer 522 remaining within the DTI gaps 520, as shown in FIG. 5L′. The insulator layer removal process may include any appropriate wet etching process, performed in a processing chamber, such as the processing chamber 120 shown in FIG. 1. The insulator layer removal process may include a wet etch process similar to or the same as the wet etch process in the DTI lateral cut process in block 420.

In block 426, a sacrificial layer removal process is performed to selectively remove the lower sacrificial layer 508 and form an inter-level isolation gap 528 between the lower channel layer 306 and the upper channel layer 308 between adjacent unit stacks of the stacking mold 504, as shown in FIG. 5M′. The sacrificial layer removal process may include any appropriate wet etching process, performed in a processing chamber, such as the processing chamber 120 shown in FIG. 1. The sacrificial layer removal process may include a wet etch process similar to or the same as the wet etch process in the recess forming recess process in block 406.

In block 428, an inter-level isolation gap fill process is performed to fill the inter-level isolation gap 528 with an inter-level isolation layer 318, as shown in FIG. 5N′. The inter-level isolation gap fill process may include any appropriate deposition process, such as chemical vapor deposition (CVD), physical vapor deposition (PVD), or the like performed in a processing chamber, such as the processing chamber 126, 128, or 130 shown in FIG. 1.

The inter-level isolation layer 318 may be formed of silicon dioxide (SiO₂), silicon oxynitride (SiON), silicon oxycarbide (SiOC), boron-doped silicon oxycarbonitride (SiOCBN).

In block 430, a nitride layer removal process is performed to selectively remove the nitride layer 526 from the WL slit 524, as shown in FIG. 5O′. The nitride layer removal process may include any appropriate wet etching process, performed in a processing chamber, such as the processing chamber 120 shown in FIG. 1. The nitride layer removal process may include a wet etch process similar to or the same as the wet etch process in the nitride layer removal process in block 418.

In block 432, a gate oxide formation process is performed to form gate oxide layers 304 on exposed inner surfaces of the WL slit 524 and the recesses 514, as shown in FIGS. 5P and 5P′. A cut-out of the semiconductor structure 500 along the YZ plane including the line A-A′ is shown in FIG. 5P. The gate oxide formation process may include any conformal deposition process, such as atomic layer deposition (ALD) process. Thickness of the deposited gate oxide layer 304 may be even more uniform than the inter-level isolation layer 318 that countered the nitride layer 526 remaining within the DTI gaps 520.

The gate oxide layers 304 may be formed of silicon oxide (SiO₂), silicon oxynitride (SiON), a high-κ dielectric material, such as hafnium oxide (HfO₂), zirconium oxide (ZrO₂), aluminum oxide (Al₂O₃), hafnium silicon oxide (HfSiO), zirconium silicon oxide (ZrSiO), tantalum pentoxide (Ta₂O₅), tantalum silicon oxide (TaSiO), or any combination thereof and have a thickness of between about 4 nm and about 8 nm, for example, about 5 nm.

In block 434, a WL slit fill process is performed to fill the WL slit 524 with a word line layer 302, as shown in FIGS. 5Q and 5Q′. The WL slit fill process may include any appropriate deposition process, such as atomic layer deposition (ALD), chemical vapor deposition (CVD), physical vapor deposition (PVD), or the like.

The word line layers 302 may be formed of tungsten (W), cobalt (Co), ruthenium (Ru), molybdenum (Mo), titanium nitride (TiN), iridium (Ir), tantalum (Ta), tantalum nitride (TaN), platinum (Pt), rhodium (Rh), or conductive oxides or nitrides thereof, or any combination thereof. A barrier metal layer (not shown) of a barrier metal material that is titanium nitride (TIN), or tantalum nitride (TaN) may be formed between the gate oxide layer 304 and the word line layer 302.

In block 436, a WL metal recess process is performed to open the transistor slit 512, as shown in FIG. 5R. The WL metal recess process may include any appropriate lithography and etch processes, such as photolithography.

The WL metal recess process in block 426 is followed by processes to form a bit line BL, source regions 310D, extension regions 312, spacer layers 314, interfaces 316 within the transistor slit 512, and processes to form a capacitor module CAP.

The embodiments described herein provide double channeled single gated three-dimensional (3D) dynamic random-access memory (DRAM) devices and methods for forming cell transistors in such 3D DRAM devices within two-color stacking mold of, for example, silicon (Si) and silicon germanium (SiGe). Due to double channels and a single inner gate sandwiched by the double channels between a source and a drain, a floating body effect caused by a high electric field induced between a drain to a gate can be reduced, and higher electrical current can be driven via the double channels. Furthermore, the double channels can be formed thin (e.g., less than about 10 nm), which further reduces a floating body effect and thus a leakage current can be reduced and dynamic retention of an OFF state can be increased. A word line layer that includes a single inner gate and a word line between the double gates can be formed with a uniform thickness, and thus with an improved resistivity, by the methods described herein.

While the foregoing is directed to embodiments of the present disclosure, other and further embodiments of the disclosure may be devised without departing from the basic scope thereof, and the scope thereof is determined by the claims that follow.

1. A memory cell array, comprising:
a plurality of memory levels stacked in a first direction, each of the plurality of memory levels comprising:
a cell transistor having:
a source region electrically connected to a bit line extending in the first direction;
a drain region;
a word line layer;
a lower channel layer electrically connected to the source region and the drain region and disposed below the word line layer in the first direction; and
an upper channel layer electrically connected to the source region and the drain region and disposed above the word line layer in the first direction; and
a cell capacitor electrically connected to the drain region; and
a plurality of inter-level isolation layers, each separating adjacent memory levels of the plurality of memory levels.

2. The memory cell array of claim 1, wherein the word line layer comprises tungsten (W), cobalt (Co), ruthenium (Ru), molybdenum (Mo), titanium nitride (TiN), iridium (Ir), tantalum (Ta), tantalum nitride (TaN), platinum (Pt), rhodium (Rh), or conductive oxides or nitrides thereof, or any combination thereof and has a thickness in the first direction of between 5 nm and 20 nm.

3. The memory cell array of claim 1, wherein the lower channel layer and the upper channel layer each comprise silicon (Si) and has a thickness in the first direction of between 5 nm and 10 nm.

4. The memory cell array of claim 1, wherein the cell transistor further comprises:
a gate oxide layer encapsulating the word line layer,
wherein the gate oxide layer comprises silicon oxide (SiO₂).

5. The memory cell array of claim 1, wherein the source region and the drain region each comprise epitaxially grown n-type doped silicon (Si).

6. The memory cell array of claim 1, wherein the cell transistor further comprises:
a first spacer layer interfacing the word line layer with the source region; and
a second spacer layer interfacing the word line layer with the drain region.

7. A method of forming cell transistors in a semiconductor memory device, comprising:
performing a word line (WL) slit fill process, to fill WL slits formed in a stacking mold with a nitride layer, wherein:
the stacking mold comprises a plurality of unit stacks, each unit stack comprising:
a lower sacrificial layer,
a lower channel layer over the lower sacrificial layer,
an upper sacrificial layer on the lower channel layer, and
an upper channel layer on the upper sacrificial layer stacked in a first direction,
each unit stack has DTI gaps partially filled with an insulator layer and extending in a second direction that is orthogonal to the first direction, and
the WL slits are each disposed between the lower channel layer and the upper channel layer between adjacent unit stacks of the stacking mold;
selectively removing the insulator layer within the DTI gaps; and
selectively removing the lower sacrificial layer and forming inter-level isolation gaps each between the lower channel layer and the upper channel layer between adjacent unit stacks of the stacking mold.

8. The method of claim 7, wherein the WL slit fill process and the gate oxide formation process each comprise an atomic layer deposition (ALD) process.

9. The method of claim 7, further comprising:
filling the inter-level isolation gaps with inter-level isolation layers; and
performing a gate oxide formation process, to form a gate oxide layer on exposed inner surfaces of the WL slit.

10. The method of claim 7, wherein:
the insulator layer comprises silicon oxide (SiO₂),
the nitride layer comprises silicon nitride (Si₃N₄),
the lower channel layer and the upper channel layer each comprise silicon (Si),
the lower sacrificial layer and the upper sacrificial layer each comprise silicon germanium (SiGe), and
the gate oxide layer comprises silicon oxide (SiO₂).

11. A method of forming cell transistors in a semiconductor memory device, comprising:
forming a transistor slit through a stacking mold in a first direction, the transistor slit extending in a second direction that is orthogonal to the first direction, the stacking mold comprising a plurality of unit stacks, each unit stack comprising:
a lower sacrificial layer,
a lower channel layer over the lower sacrificial layer,
an upper sacrificial layer on the lower channel layer, and
an upper channel layer on the upper sacrificial layer stacked in the first direction;
performing a recess forming process, to form recesses in the upper sacrificial layers from sidewalls of the transistor slit;
forming a first insulator layer on exposed surfaces of the lower channel layers and the upper channel layers within the transistor slit and the recesses;
filling the transistor slit and the recesses with a first nitride layer;
performing a deep trench isolation (DTI) lateral cut process, to form DTI gaps through the stacking mold in the first direction, the DTI gaps extending in a third direction that is orthogonal to the first and second directions;
filling the DTI gaps with a second insulator layer;
selectively removing the first nitride layer from the transistor slit and the recesses;
forming word line (WL) slits each between the lower channel layer and the upper channel layer between adjacent unit stacks of the stacking mold;
performing a WL slit fill process, to fill the WL slits and the recesses with a second nitride layer;
selectively removing the second insulator layer;
selectively removing the lower sacrificial layer and forming inter-level isolation gaps each between the lower channel layer and the upper channel layer between adjacent unit stacks of the stacking mold;
filling the inter-level isolation gaps with inter-level isolation layers;
performing a gate oxide formation process, to form a gate oxide layer on exposed inner surfaces of the WL slit and the recesses; and
performing a WL slit fill process, to fill the WL slits with a word line layer.

12. The method of claim 11, wherein the DTI lateral cut process comprises a wet etch process.

13. The method of claim 11, wherein the WL slit fill process comprises chemical vapor deposition (CVD) process and the gate oxide formation process comprises an atomic layer deposition (ALD) process.

14. The method of claim 11, wherein the lower channel layer and the upper channel layer each comprise silicon (Si) and has a thickness in the first direction of between 5 nm and 10 nm.

15. The method of claim 11, wherein:
the lower sacrificial layer and the upper sacrificial layer each comprise silicon germanium (SiGe),
the lower sacrificial layer has a thickness in the first direction of between 8 nm and 15 nm, and
the upper sacrificial layer has a thickness in the first direction of between 30 nm and 60 nm.

16. The method of claim 11, wherein the first insulator layer and the second insulator layer each comprise silicon oxide (SiO₂).

17. The method of claim 16, wherein the first nitride layer and the second nitride layer each comprise silicon nitride (Si₃N₄).

18. The method of claim 11, wherein the gate oxide layer comprises silicon oxide (SiO₂).

19. The method of claim 11, further comprising:
subsequent to the recess forming process, performing a channel trimming process to partially remove portions of the lower channel layer and the upper channel layer that are adjacent to each of the recesses in the first direction.

20. The method of claim 7, further comprising:
subsequent to the WL slit fill process, performing a WL metal recess process, to open the transistor slit.
